(19) United States
(12) Patent Application Publication
(10) Pub. No.: US 2024/0349472 A1
(43) Pub. Date: Oct. 17, 2024

(54) COMPONENT MOUNTER

(71) Applicant: FUJI CORPORATION, Chiryu (JP)

(72) Inventor: Hiroshi SUGIYAMA, Anjo-shi (JP)

(73) Assignee: FUJI CORPORATION, Chiryu (JP)

(21) Appl. No.: 18/294,640

(22) PCT Filed: Aug. 27, 2021
(86) PCT No.: PCT/JP2021/031459

§ 371 Date: Feb. 2, 2024

(51) Int. Cl. H05K 13/04

(52) U.S. Cl. CPC H05K 13/0419

(57) ABSTRACT

The component mounter includes a base including a table attachment section, a feeder table mounted with a tape feeder configured to feed a carrier tape that accommodates multiple components and supply the components to a predetermined supply position, the feeder table being attached to the table attachment section, and a cover provided on the feeder table so as to be changeable between a closed state in which an upper portion of the tape feeder excluding the supply position is covered and an open state in which the upper portion is open.

### TECHNICAL FIELD

The present description relates to a component mounter using a tape feeder.

### BACKGROUND ART

A technique for mass-producing board products by performing board work on a board on which a circuit pattern is formed is widespread. As a representative example of a board work machine, there is a component mounter that performs mounting work of a component. Many component mounters use a tape feeder that pulls out and feeds a carrier tape that accommodates multiple components from a reel. When the mounting work progresses and the carrier tape is used up to the end, the operator exchanges the reel or exchanges the tape feeder to supply the component. Also, in many cases where the type of the board product is changed, the operator collectively exchanges multiple reels or multiple tape feeders. In the conventional art, a cover has been provided for the purpose of ensuring safety of the tape feeder during operation, and the like. Patent Literature 1 discloses an example of a technique related to a cover that covers a tape feeder.

A component mounting device disclosed in Patent Literature 1 includes a component supply space in which a component supply unit (tape feeder) is disposed by insertion of a wheeled platform, a mounting space in which a component is mounted on a board by using a head unit having a nozzle, a cover unit that separates the mounting space from the component supply space and enables the head unit to operate during exchange of the wheeled platform, and a nozzle preparation unit provided in the cover unit. According to this, the occupancy ratio of the nozzle preparation unit in the component mounting device can be reduced. Further, according to the description of the embodiment, by horizontally moving a shutter member constituting the cover unit, the nozzle closes the opening for picking up the component, and the mounting space and the component supply space can be completely isolated.

### PATENT LITERATURE

Patent Literature 1: JP-A-2017-157688

### SUMMARY OF THE INVENTION

### Technical Problem

However, not only the configuration of Patent Literature 1 but also a component mounter may generally perform a setup change using another reel instead of the reel around which the carrier tape in use is wound. In this case, the tape feeder rewinds the carrier tape in a reverse direction as compared with the normal operation, and the operator needs to remove the reel and wind the carrier tape. When a cover such as a cover unit exemplified in Patent Literature 1 is present when the carrier tape is rewound, the rewinding operation of the carrier tape may be inhibited, the carrier tape may be damaged, or a setup change work of the operator may be complicated.

Therefore, an object of the present description is to provide a component mounter capable of smoothly rewinding a carrier tape in use in a tape feeder in a reverse direction.

### Solution to Problem

The present description discloses a component mounter including a base including a table attachment section, a feeder table mounted with a tape feeder configured to feed a carrier tape that accommodates multiple components and supply the components to a predetermined supply position, the feeder table being attached to the table attachment section, and a cover provided on the feeder table so as to be changeable between a closed state in which an upper portion of the tape feeder excluding the supply position is covered and an open state in which the upper portion is open.

### Advantageous Effect of the Invention

In the disclosed component mounter, when the carrier tape in use is rewound in a reverse direction, since the cover can be set to an open state to widely open the direction in which the carrier tape returns, the carrier tape can be smoothly rewound in the reverse direction. Further, when the carrier tape is not rewound in the reverse direction, the cover can be set to a closed state to maintain the original function of the cover.

### BRIEF DESCRIPTION OF DRAWINGS

FIG. 1 is a plan view schematically illustrating an overall configuration of a component mounter of an embodiment.

FIG. 2 is a perspective view of a component supply wheeled platform configured with including a feeder table, and illustrates a closed state of a cover.

FIG. 3 is a side view illustrating a state in which a tape feeder is mounted on the feeder table, and illustrates a closed state of the cover.

FIG. 4 is a perspective view of the component supply wheeled platform, and illustrates an open state of the cover when a carrier tape is rewound in a reverse direction.

FIG. 5 is a side view illustrating a state in which the tape feeder is mounted on the feeder table, and illustrates a state in which the carrier tape is rewound in a reverse direction with the cover in the open state.

FIG. 6 is a partial perspective view illustrating a configuration of an entry restriction section as viewed from a direction of an arrow A1 in FIG. 1.

FIG. 7 is a partial perspective view illustrating a configuration of an opening restriction section and a detection section, and illustrates a state in which the feeder table is being attached to a table attachment section.

FIG. 8 is a partial perspective view illustrating a configuration of the opening restriction section and the detection section, and illustrates a state in which the feeder table is attached to table attachment section.

FIG. 9 is a partial side view of the state of FIG. 8 as viewed from a side, and the detection section detects a good mounting state of the multiple tape feeders.

### DESCRIPTION OF EMBODIMENTS

### 1. Overall Configuration of Component Mounter 1 According to Embodiment

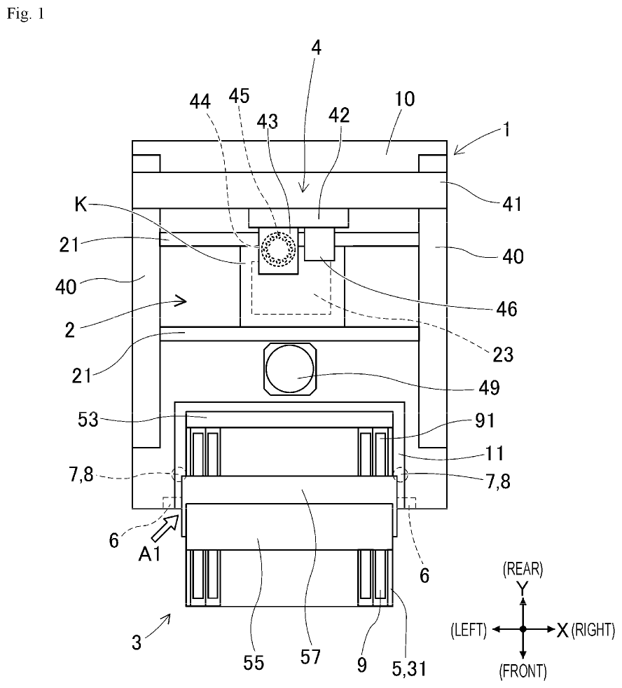

An overall configuration of component mounter 1 according to the embodiment will be described with reference to FIG. 1. Component mounter 1 performs mounting work for mounting a component on board K. A direction from left toward right on the drawing surface in FIG. 1 in which board K is conveyed is an X-axis direction, and a direction from the bottom (front side) toward the top (rear side) on the drawing surface is a Y-axis direction. Component mounter 1 includes board conveyance device 2, component supply device 3, component transferring device 4, base 10, a control device (not illustrated), and the like.

Board conveyance device 2 includes pair of guide rails 21, pair of conveyance belts (not illustrated), clamp mechanism 23, and the like. Pair of guide rails 21 extend in the X-axis direction across a slightly rear side of an upper surface of base 10, and are assembled to base 10 in parallel with each other. Pair of conveyance belts rotate along guide rails 21 in a state in which two parallel sides of board K are placed, and convey in board K to a work performing position in the vicinity of the center of base 10. Clamp mechanism 23 pushes up conveyed board K, clamps board K with guide rails 21, and positions board K. After the mounting work of the component by component transferring device 4 ends, clamp mechanism 23 releases board K, and the conveyance belts convey out board K to the outside of the machine.

Component supply device 3 includes feeder table 5 and multiple tape feeders 9. Feeder table 5 is detachably provided to table attachment section 11 provided at an upper portion of the front side of base 10. Feeder table 5 is formed in a substantially rectangular shape in plan view. Multiple tape feeders 9 are mounted on feeder table 5 to be arranged in the left-right direction. Feeder table 5 is incorporated in component supply wheeled platform 31 to improve the efficiency of the movement and the attachment and detachment work (details will be described later). The configuration is not limited to this, and feeder table 5 may be formed in a portable single body shape.

Tape feeder 9 pulls out and feeds carrier tape T from reel R (see FIG. 3), and supplies the component such that the component can be collected at supply position 91 close to the rear end. Tape feeder 9 is formed into a thin type having a small width dimension in a left-right direction. Tape feeder 9 is allowed to mix multiple types corresponding to a difference in the tape width dimension of carrier tape T and to mix multiple types having different internal configurations. A configuration example of tape feeder 9 will be described in detail later.

Component transferring device 4 includes pair of guide rails 40, Y-axis moving body 41, X-axis moving body 42, mounting head 43, rotary tool 44, suction nozzle 45, board recognition camera 46, component recognition camera 49, and the like. Pair of guide rails 40 are disposed on a left edge and a right edge of base 10, and extend in the Y-axis direction in parallel with each other while being separated from each other. Y-axis moving body 41 is formed of a member long in the X-axis direction and is mounted on pair of guide rails 40. Y-axis moving body 41 is driven by a Y-direction driving mechanism (not illustrated) to move in the Y-axis direction. X-axis moving body 42 is mounted on Y-axis moving body 41 and is driven by an X-direction driving mechanism (not illustrated) to move in the X-axis direction.

Mounting head 43 is provided on a front surface of X-axis moving body 42, and moves in two horizontal directions together with X-axis moving body 42. Rotary tool 44 is rotatably provided below the mounting head 43. Rotary tool 44 rotates around a vertical central axis. Rotary tool 44 includes multiple (twelve in the example of FIG. 1) suction nozzles 45 at equal distances from the vertical central axis. Suction nozzle 45 is a form of a component mounting tool that mounts a component at a predetermined mounting position of board K. Suction nozzle 45 performs lifting and lowering operations and a rotating operation around the vertical axis. When rotary tool 44 rotates, suction nozzle 45 revolves around the vertical central axis of rotary tool 44. Suction nozzle 45 is selectively supplied with air of a negative pressure or a positive pressure from an air supply mechanism (not illustrated), and picks up and mounts a component. Alternatively, rotary tool 44 may be omitted, and one suction nozzle 45 may be rotatably provided below mounting head 43.

Board recognition camera 46 is provided on X-axis moving body 42 alongside mounting head 43. Board recognition camera 46 is disposed such that an optical axis is directed downward, and images a position reference mark attached to board K from above. The acquired image data is subjected to image processing, so that the work performing position of board K is accurately obtained. Examples of board recognition camera 46 include a digital imaging device having an imaging element such as a charge coupled device (CCD) or a complementary metal oxide semiconductor (CMOS).

Component recognition camera 49 is provided on base 10 between board conveyance device 2 and component supply device 3. Component recognition camera 49 is disposed such that an optical axis is directed upward. Component recognition camera 49 images the component held by suction nozzle 45 from the bottom side and recognizes the component while mounting head 43 moves from component supply device 3 to board K. As a result, it is determined whether the type of the component is correct or incorrect, and the position and direction of the component with respect to suction nozzle 45 are detected and reflected in the mounting work. Examples of component recognition camera 49 include a digital imaging device having an imaging element such as a CCD or a CMOS.

Component transferring device 4 can repeat multiple pickup and mounting cycles for board K of which the position is determined. In a pickup and mounting cycle, first, mounting head 43 moves above component supply device 3, and each of suction nozzles 45 picks up the component. Next, mounting head 43 moves above component recognition camera 49, and component recognition camera 49 performs imaging. Next, mounting head 43 moves above board K, and each of suction nozzles 45 mounts the component on board K. Then, mounting head 43 moves toward component supply device 3 again. The pickup and mounting cycle is a generic term of the above-described series of operations.

A control device (not illustrated) is assembled to base 10, and an installation position thereof is not particularly limited. The control device includes a computer device having CPU and operated with software. The control device may be configured such that multiple CPUs are distributed and disposed in the device and connected in communication with each other. The control device controls board conveyance device 2, component supply device 3, and component transferring device 4 based on the mounting work data created for each type of board K, and advances the component mounting work. The mounting work data is data describing a detailed procedure of the mounting work, a method of performing the mounting work, and the like. The mounting work data includes information such as the type and number of components to be mounted and tape feeder 9 to be used.

### 2. Configuration Example of Tape Feeder 9

Next, a configuration example of tape feeder 9 will be described with reference to FIG. 3. As illustrated in the drawing, tape feeder 9 is formed to be a small rear portion and a large front portion that expands downward. Tape feeder 9 has a protruding section (not illustrated) protruding downward from the bottom surface of the rear portion. Tape feeder 9 has reel holding section 92 that rotatably holds the peripheral edge of reel R in a front lower portion. Reel R is a rotating body around which carrier tape T (indicated by thick lines in FIGS. 3 and 5) accommodating multiple components is wound. In carrier tape T, cavity sections for accommodating components one by one are formed at a constant pitch. Further, carrier tape T is provided with a large number of sprocket holes at a predetermined pitch on one side in the tape width direction.

Tape feeder 9 includes tape guide 93 that guides carrier tape T to supply position 91. Tape guide 93 starts from the upper rear side of reel holding section 92, is inclined obliquely rearward and upward at the beginning, extends horizontally rearward from the middle, and reaches supply position 91. Tape feeder 9 further includes tape peeling section 94. Tape peeling section 94 is formed to include the rear portion of tape guide 93 and supply position 91. Tape peeling section 94 can temporarily open the cavity section of carrier tape T to take out components.

Carrier tape T having passed through supply position 91 is further fed rearward and then lowered to reach tape cutting mechanism 12 provided on base 10. Tape cutting mechanism 12 cuts the used portion on the distal end side of carrier tape T to generate a discharge tape. The cut discharge tape falls toward discharge tape storage section 38 disposed on the lower side. Accordingly, the used portion on the distal end side of carrier tape T is usually less than or equal to a certain length.

In addition, tape feeder 9 includes sprocket 95 and drive motor 96 as drive mechanisms for feeding carrier tape T. Sprocket 95 is rotatably provided below tape guide 93 on the front side of supply position 91. The teeth of sprocket 95 pass upward through the cutout section formed in tape guide 93 and engage with the sprocket hole of carrier tape T.

Drive motor 96 is connected to a rotary shaft of sprocket 95. Drive motor 96 rotates forward to drive sprocket 95 in a front direction of rotation so as to feed carrier tape T in a predetermined supply direction. In addition, drive motor 96 reversely rotates to drive sprocket 95 in a reverse rotation so as to return (rewind) carrier tape T in the reverse direction of the supply direction. Drive motor 96 can be automatically controlled during normal operation, and can be manually operated by the operator during standby and the like. Multiple sprockets 95 may be provided at different positions of tape guides 93, and multiple drive motors 96 may be provided correspondingly.

When reel R is removed from tape feeder 9, the used reel R has no carrier tape T. Therefore, the operator can easily remove reel R from reel holding section 92. Conversely, carrier tape T still remains on reel R in use, and the teeth of sprocket 95 are engaged with the sprocket holes of carrier tape T. Therefore, the operator cannot wind carrier tape T around reel R.

Accordingly, the operator first reversely rotates drive motor 96 by the manual operation to rewind carrier tape T and resolve the engaged state with sprocket 95. Next, the operator removes reel R from reel holding section 92 and winds carrier tape T around reel R. The removal work of reel R described above is performed in the external setup area outside component mounter 1. That is, the removal work of reel R is not performed in a state in which feeder table 5 is attached to table attachment section 11, and is performed after feeder table 5 is removed.

### 3. Feeder Table 5 and Component Supply Wheeled Platform 31

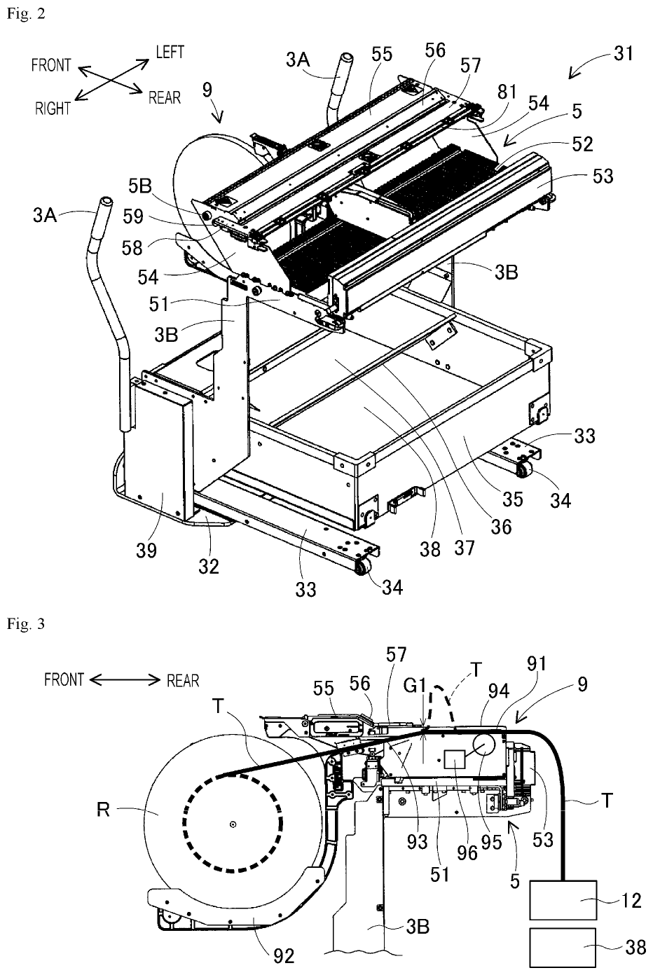

Next, component supply wheeled platform 31 including feeder table 5 will be described with reference to FIGS. 2 to 5. Component supply wheeled platform 31 includes, in addition to feeder table 5, bottom plate 32, pair of left and right leg members 33, storage box 35, pair of left and right side plate members 39, and the like. Bottom plate 32 is a flat plate-shaped member elongated in the left-right direction, and is disposed in parallel with the floor surface near the floor surface.

Pair of left and right leg members 33 are elongated members extending in the front-rear direction. Pair of left and right leg members 33 are provided on the left side and the right side of the upper surface of bottom plate 32 so as to be separated from each other and parallel to each other, and protrude in the front-rear direction from bottom plate 32. Each of leg members 33 is formed of, for example, shape steel having a crank-shaped cross section that opens downward. Wheels 34 that travel on the floor surface are provided at the front end portion and the rear end portion of the lower surface of leg member 33. At least one of front and rear wheels 34 is a free wheel of which the traveling direction is variable.

Storage box 35 is formed in a rectangular parallelepiped shape that opens upward. Storage box 35 is disposed above bottom plate 32 and can be pulled out forward. Storage box 35 is partitioned into equipment storage section 37 on the front side and discharge tape storage section 38 on the rear side by partition plate 36 that is obliquely disposed near the middle in the front-rear direction. Equipment storage section 37 can store equipment such as suction nozzle 45, general-purpose tools, and components such as reel R, which are exchanged and used in component mounter 1. Discharge tape storage section 38 stores the above-described discharge tape.

Pair of left and right side plate members 39 are provided to stand from the left edge and the right edge of bottom plate 32. Round-rod shaped operation handle 3A bent upward is provided near the front of each of side plate members 39. The operator can move component supply wheeled platform 31 and attach feeder table 5 by operating left and right operation handles 3A. On an inner side surface of each of side plate members 39, flat plate-shaped arm 3B that is further bent rearward and upward is provided. When feeder table 5 is attached to table attachment section 11, arm 3B is disposed close to the front end of component mounter 1. Feeder table 5 is horizontally provided so as to extend between the upper ends of left and right arms 3B.

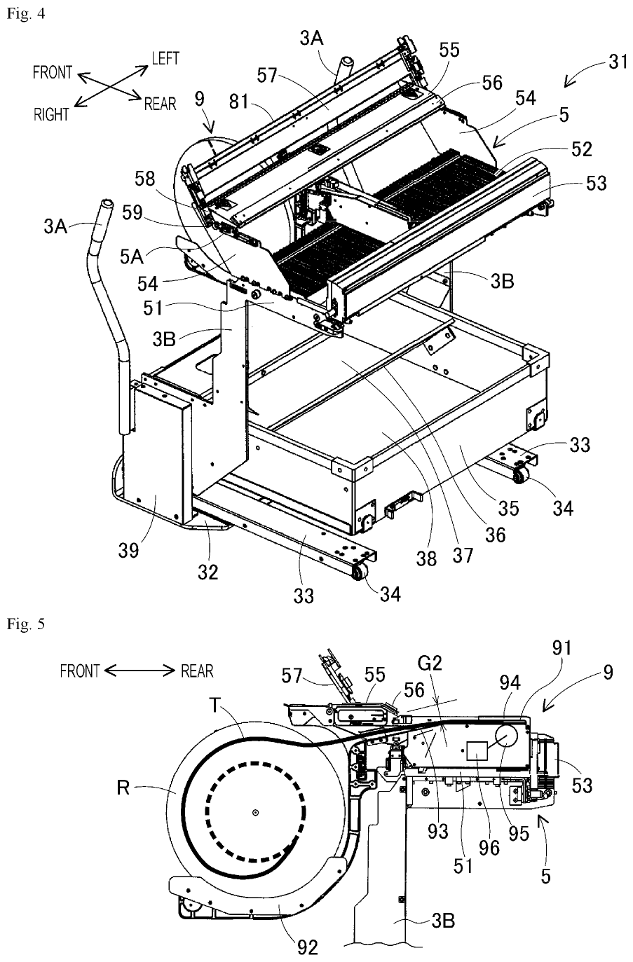

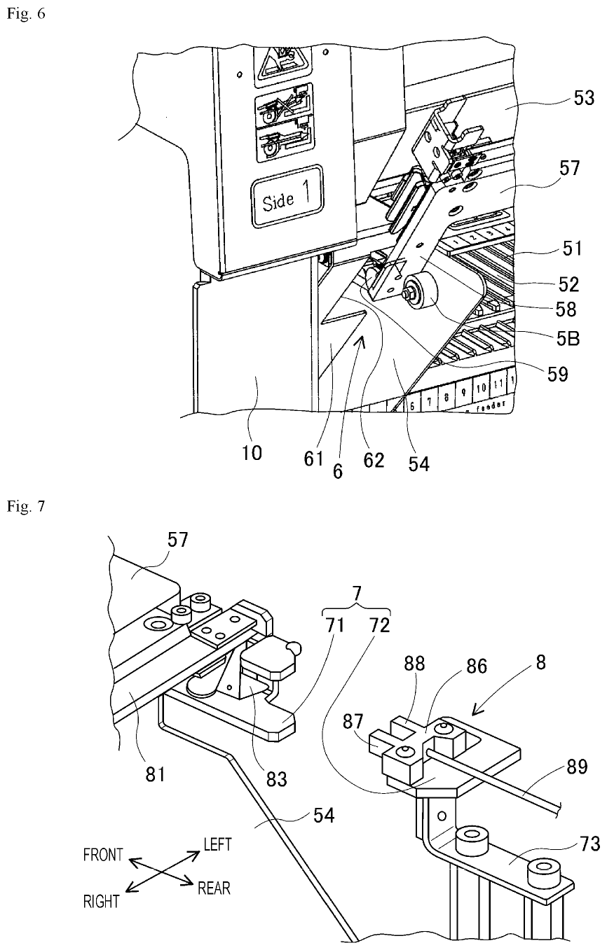

Feeder table 5 includes bottom plate section 51, connecting section 53, pair of left and right side plates 54, fixing cover 55, movable cover 57, and the like. Bottom plate section 51 is a rectangular plate-shaped member that is horizontally disposed. Multiple groove-shaped slots 52 extending in the front-rear direction and arranged at a predetermined pitch in the left-right direction are formed on the upper surface of bottom plate section 51 (see FIG. 6). Slot 52 is a form of a mounting position at which tape feeder 9 is mounted. In FIGS. 2 and 4, a large number of outline lines representing the shapes of multiple slots 52 appear black in an overlapping manner.

The protruding section of the bottom surface of the rear portion of tape feeder 9 is inserted rearward from the front side of slot 52. As a result, tape feeder 9 is mounted on feeder table 5. Large-sized tape feeder 9 having a large width dimension is mounted by occupying multiple slots 52. In FIGS. 2 and 4, one tape feeder 9 is exemplified, and multiple tape feeders 9 are actually mounted side by side in the left-right direction.

Connecting section 53 is provided upright from the rear edge of bottom plate section 51. A table side positioning section and a table side connector (not illustrated) are provided on the front surface of the connecting section 53 so as to correspond to the position of each of slots 52. Meanwhile, a feeder side positioning section and a feeder side connector (not illustrated) are provided on the rear surface of tape feeder 9. When tape feeder 9 is inserted into the innermost portion of slot 52, the feeder side positioning section automatically engages with the table side positioning section to determine the mounting position of tape feeder 9. At the same time, the feeder side connector is automatically fitted into the table side connector, and power supply and communication connection from feeder table 5 to tape feeder 9 are performed.

Pair of left and right side plates 54 are provided to stand at positions above left and right arms 3B of bottom plate section 51. Fixing cover 55 is a plate-shaped member elongated in the left-right direction. Fixing cover 55 extends horizontally at a position near the front of the upper edges of left and right side plates 54. A rear portion of fixing cover 55 is inclined section 56 that is bent obliquely in a rear-down direction.

Cover 57 is a plate-shaped member elongated in the left-right direction. Cover 57 extends over a position near the rear of the upper edges of left and right side plates 54. Swing arms 58 extending forward are provided on both left and right sides of cover 57. Distal ends of swing arms 58 are rotatably and swingably supported by swing shafts 59 provided on outer side surfaces of left and right side plates 54. As a result, cover 57 rotates and swings around swing shaft 59 according to the opening and closing operation of the operator. Rear side stopper 5A is provided on the outer side surface of side plate 54 at a position on the rear side of swing shaft 59 (see FIG. 4). Further, front side stopper 5B is provided on the outer side surface of side plate 54 at a position on the front side of swing shaft 59 (see FIG. 2).

Cover 57 rotates and swings rearward until cover 57 comes into contact with rear side stopper 5A and takes a substantially horizontal posture. At this time, cover 57 is in a closed state of covering the upper side of tape feeder 9 except for supply position 91. Cover 57 functions equivalently as one large cover by having the front edge thereof overlap inclined section 56 and being combined with fixing cover 55. Further, cover 57 rotates and swings forward until cover 57 comes into contact with front side stopper 5B, and takes an inclined posture of substantially 60° (see FIG. 5). At this time, cover 57 is positioned above fixing cover 55. In other words, cover 57 rotates and swings forward by substantially 120° from the closed state, and changes to the open state in which the upper side of tape feeder 9 is opened.

As illustrated in FIG. 3, fixing cover 55 and cover 57 in the closed state cover at least a part of an area between reel R and tape peeling section 94 above tape feeder 9. In other words, fixing cover 55 and cover 57 in the closed state cover a range in which the upper side of tape guide 93 is opened. Cover 57 in the closed state may be a shape that extends to come into contact with tape peeling section 94. Fixing cover 55 and cover 57 in the closed state prevent carrier tape T fed along tape guide 93 from being bent and loosened upward.

Here, the original function of fixing cover 55 and cover 57 in the closed state can be referred to as a safety cover. That is, fixing cover 55 and cover 57 in the closed state prevent the operator from coming into contact with tape feeder 9 in operation. In particular, fixing cover 55 and cover 57 in the closed state prevent the operator from coming into contact with carrier tape T to be fed, and ensure high safety.

The configuration is not limited to this, and the original function of fixing cover 55 and cover 57 in the closed state may be a guide cover. That is, fixing cover 55 and cover 57 in the closed state can guide tape feeder 9 to slot 52 (mounting position) by adjusting the height position of tape feeder 9 held by the operator so as not to be too high.

Meanwhile, as illustrated in FIG. 3, gap dimension G1 between cover 57 in the closed state and tape guide 93 is a small narrow path. Therefore, when drive motor 96 is reversely rotated to rewind carrier tape T, the rewinding operation may be inhibited by cover 57. That is, as indicated by the thick broken line, carrier tape T may be caught by cover 57 and bent upward. In particular, carrier tape T is likely to be caught in large-sized tape feeder 9 having a large tape width dimension.

When carrier tape T is caught, a length area in which carrier tape T is bent and cannot be used may be generated, or damage may occur, such as a component falling out of some cavity sections. Further, the setup change work of the operator who winds carrier tape T around reel R is complicated. This problem occurs frequently in the configuration in the conventional art including a large fixing cover comparable to the total size of fixing cover 55 and cover 57 in a closed state.

In the present embodiment, the operator opens cover 57 to the open state before reversely rotating drive motor 96, as illustrated in FIGS. 4 and 5. As a result, the narrow path having gap dimension G1 disappears. Instead, a narrow path having gap dimension G2 is generated between fixing cover 55 and tape guide 93 (see FIG. 5). Also in this case, gap dimension G2 is secured to be about three times or more gap dimension G1. That is, by changing cover 57 to the open state, the return direction of carrier tape T can be widely opened. As a result, carrier tape T can be smoothly rewound in the reverse direction, and carrier tape T is less likely to be caught.

### 4. Entry Restriction Section 6

Next, entry restriction section 6 will be described with reference to FIGS. 1 and 6. As illustrated in FIG. 1, entry restriction sections 6 are provided in a form of a pair of left and right entry restriction sections at positions near the left and right front ends of table attachment section 11. Entry restriction section 6 allows feeder table 5 to enter table attachment section 11 when cover 57 is in the closed state, and restricts feeder table 5 from entering table attachment section 11 when cover 57 is in the open state. Entry restriction section 6 reliably maintains the original function of cover 57 during the operation of component mounter 1 by necessarily attaching feeder table 5 when cover 57 is in the closed state.

Entry restriction section 6 includes a restricted member provided on cover 57 and entry restriction member 61 provided on base 10. The restricted member is a member that changes at least one of the position or posture between the closed state and the open state of cover 57. In the present embodiment, swing arm 58 of cover 57 or cover 57 itself functions as a restricted member.

Meanwhile, as illustrated in FIG. 6, entry restriction member 61 provided on base 10 is disposed close to the outside of side plate 54 of feeder table 5 moving in the front-rear direction. Entry restriction member 61 has crank-shaped cutout section 62 that opens inward side plate 54. Cutout section 62 allows cover 57 in the horizontal posture in the closed state to enter and pass therethrough. Meanwhile, cutout section 62 restricts entry of cover 57 in the inclined posture in the open state.

That is, as illustrated in FIG. 6, cover 57 or swing arm 58 in the inclined posture comes into contact with the upper edge of cutout section 62 and cannot enter cutout section 62. The size and position of the crank shape of cutout section 62 are designed such that entry restriction member 61 performs the above-described operation. As a result, feeder table 5 is prevented beforehand from being attached when cover 57 is in the open state.

### 5. Opening Restriction Section 7

Next, opening restriction section 7 will be described with reference to FIGS. 1 and 7 to 9. As illustrated in FIG. 1, opening restriction sections 7 are provided in a form of a pair of left and right opening restriction sections at positions on the rear side of left and right entry restriction sections 6 of table attachment section 11. Opening restriction section 7 restricts a change of cover 57 from the closed state to the open state in a state in which feeder table 5 is attached. Opening restriction section 7 prevents the operator from erroneously setting cover 57 to the open state beforehand during the operation interruption of component mounter 1, and the like, and reliably maintains the original function of cover 57.

Opening restriction section 7 includes locked member 71 provided on cover 57 and opening restriction member 72 provided on base 10. As illustrated in FIG. 7, locked members 71 are attached to the rear portions of both the left and right sides of cover 57 in the closed state. Locked member 71 is a plate-shaped member disposed horizontally, and is disposed at a position lower than the main body of cover 57.

Meanwhile, opening restriction member 72 provided on base 10 is a plate-shaped member disposed horizontally. Opening restriction member 72 is fixed at a position slightly higher than locked member 71 by using attachment member 73. Opening restriction member 72 locks locked member 71 of cover 57 in the closed state to restrict the rotational swing of cover 57. In the present embodiment, opening restriction member 72 also serves as a member for supporting photoelectric sensor 86 described later. As a result, the number of components is reduced, and the material cost and the assembly work cost are reduced.

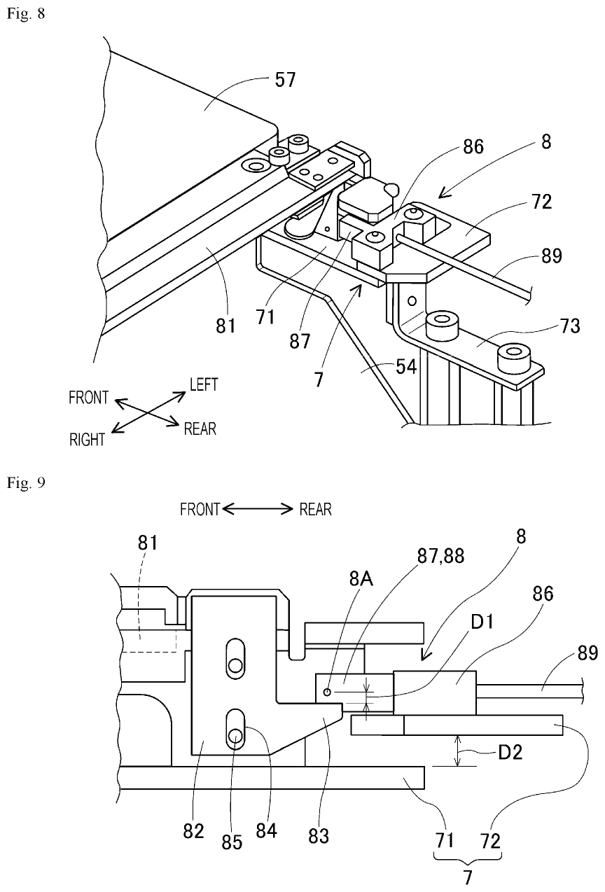

When feeder table 5 is attached, as illustrated in FIGS. 8 and 9, locked member 71 enters the lower side of opening restriction member 72. Accordingly, when the operator tries to open cover 57, locked member 71 rises and comes into contact with opening restriction member 72, but the subsequent rising is restricted by opening restriction member 72. As a result, cover 57 maintains the closed state without rotating and swinging.

### 6. Detection Section 8

Next, detection section 8 will be described with reference to FIGS. 1 and 7 to 9. As illustrated in FIG. 1, detection section 8 is provided in a form of a pair of left and right detection sections, with main configuration members disposed at positions overlapping opening restriction section 7. Detection section 8 detects a mounting state of multiple tape feeders 9 mounted on feeder table 5. Detection section 8 includes detection bar 81, sensor dog 82, and photoelectric sensor 86.

As illustrated in FIGS. 7 and 8, detection bar 81 is provided on the rear side of cover 57. Detection bar 81 is a band plate-shaped member that is substantially the same as the width dimension of cover 57 in the left-right direction. Detection bar 81 is disposed at a position slightly higher than the upper surfaces of multiple tape feeders 9 mounted on feeder table 5. The height position of detection bar 81 with respect to cover 57 can be finely adjusted to correspond to individual differences in the height dimensions of multiple tape feeders 9, and the like.

Sensor dogs 82 are provided above locked members 71 on both left and right sides of cover 57 in the closed state (see FIG. 9). Sensor dog 82 is a plate-shaped member disposed to stand, and has light blocking section 83 on the rear side. Sensor dog 82 has two long holes 84 that are long in an up-down direction. Each of long holes 84 is displaceable in the up-down direction with respect to pin member 85 on the side of cover 57. As a result, sensor dog 82 can finely adjust the height position with respect to photoelectric sensor 86. Sensor dog 82 is lifted and lowered integrally with cover 57 and detection bar 81.

Meanwhile, photoelectric sensor 86 is supported on the upper surface of opening restriction member 72 on the side of base 10. Photoelectric sensor 86 includes light projecting section 87, light receiving section 88, and output cable 89. Light projecting section 87 and light receiving section 88 are disposed on the left and right sides with light blocking section 83 of sensor dog 82 interposed therebetween. Light projecting section 87 emits detection light 8A (see FIG. 9) toward light receiving section 88. Light receiving section 88 detects the amount of received detection light 8A, in other words, detects whether detection light 8A is blocked by light blocking section 83. Photoelectric sensor 86 outputs the detection result to the control device via output cable 89.

As illustrated in FIG. 9, when multiple tape feeders 9 are in a good mounting state, light blocking section 83 of sensor dog 82 is positioned below the path of detection light 8A. At this time, light receiving section 88 detects a sufficient amount of detection light 8A, and photoelectric sensor 86 outputs a detection result that the mounting state is good. Separation distance D1 between the upper edge of light blocking section 83 and the path of detection light 8A is set to be smaller than separation distance D2 between locked member 71 and opening restriction member 72 in opening restriction section 7.

Here, it is assumed that the mounting state of one or more tape feeders 9 is not good. As described above, tape feeder 9 is mounted by inserting the protruding section of the bottom surface into slot 52. However, it is not uncommon for tape feeder 9 to be mounted in a state in which the protruding section is not inserted into slot 52 and rides on the bottom plate section 51. In this case, tape feeder 9 pushes up detection bar 81 because tape feeder 9 is mounted while floating higher than the normal height position (a mounting state that is not good).

As a result, detection bar 81, cover 57, locked member 71, and sensor dog 82 are in a state of being integrally raised. Strictly speaking for cover 57, cover 57 is displaced upward while rotating and swinging in the direction from the closed state to the open state. Light blocking section 83 of sensor dog 82 blocks detection light 8A before locked member 71 comes into contact with opening restriction member 72. Accordingly, light receiving section 88 detects disappearance or decrease of detection light 8A, and photoelectric sensor 86 outputs a detection result indicating that the mounting state is not good. Since pair of left and right detection sections 8 are provided, although detection bar 81 and cover 57 are raised while being inclined in the left-right direction, a detection result that the mounting state is not good is obtained. The control device that receives the detection result does not start the mounting work of component mounter 1, and notifies the operator of the abnormality of component supply device 3.

### 7. Setup Change Work Related to Component Mounter 1

Next, the setup change work related to component mounter 1 will be described. In component mounter 1, when the production performance number of a certain board product reaches the target number, a setup change work using another reel R instead of reel R around which carrier tape T in use is wound is required. The setup change work is performed in the external setup area as described above, and the production preparation of the next board product is completed.

At the beginning of the setup change work, the operator separates component supply wheeled platform 31 from component mounter 1 and moves component supply wheeled platform 31 to the external setup area. The external setup area includes a setup device capable of supplying power to feeder table 5 and controlling the operation of tape feeder 9. Therefore, each of tape feeders 9 to which power is supplied via feeder table 5 is in an operable state. Next, the operator performs an open operation of cover 57 from the closed state to the open state. Since tape feeder 9 is not in operation and cover 57 is in the closed state, it is not necessary to ensure safety, so that the opening operation does not cause any trouble. In addition, the opening operation can be performed because opening restriction member 72 remains on the side of component mounter 1 and opening restriction section 7 does not function.

Next, the operator rewinds carrier tape T in use in the reverse direction in each of tape feeders 9. At this time, the waiting time of the operator can be shortened by the multiple tape feeders 9 simultaneously rewinding under the control of the setup device. In addition, the operator maintains the current mounting state of tape feeder 9 continuously used for the next board product without rewinding carrier tape T.

Since cover 57 is in the open state during rewinding, carrier tape T is not caught by cover 57. As a result, as illustrated in FIG. 5, carrier tape T is in a loosened state inside or in the vicinity of reel R. Accordingly, the occurrence of damage to carrier tape T is resolved.

Further, the operator removes each of tape feeders 9 from feeder table 5. At this time, since carrier tape T is not caught by cover 57 in the closed state, the removal work is easy. Next, the operator removes reel R from reel holding section 92 of each of tape feeders 9 and winds carrier tape T around reel R. At this time, since carrier tape T is loosened in the vicinity of reel R, the winding operation is easy. Depending on the structure of tape feeder 9, the operator may remove and set reel R in a state in which tape feeder 9 is mounted on feeder table 5. Also in this case, the work is easy.

Next, the operator sets new reel R in reel holding section 92 for each of multiple tape feeders 9, and pulls out carrier tape T and loads carrier tape T until it engages with sprocket 95. Further, the operator performs a close operation of cover 57 from the open state to the closed state, and then mounts multiple tape feeders 9 on feeder table 5. As a result, the setup of component supply wheeled platform 31 is ended. Thereafter, the operator moves component supply wheeled platform 31 to component mounter 1 and attaches feeder table 5 to table attachment section 11.

During the attachment, when cover 57 remains in the open state, feeder table 5 cannot be attached due to the operation of entry restriction section 6. Accordingly, the operator performs a close operation of cover 57 to the closed state on the spot (at the front side position of component mounter 1) and retries the attachment of feeder table 5. Thus, the attachment of feeder table 5 is ended, and the production preparation of the next board product is completed.

When the mounting state of tape feeder 9 is not good, the control device notifies the operator of the fact based on the detection result of detection section 8. The operator once separates component supply wheeled platform 31 from component mounter 1, visually checks tape feeder 9 on the spot, and reinserts tape feeder 9 into slot 52. Since the number of tape feeders 9 in which the mounting state is not good is not limited to one, the operator carefully performs visual check and insertion to avoid leakage. Further, when the operator again attaches feeder table 5, preparation for production of the next board product is completed.

In component mounter 1 of the embodiment, when carrier tape T in use is rewound in the reverse direction, since cover 57 can be set to the open state to widely open the return direction of carrier tape T, carrier tape T can be smoothly rewound in the reverse direction. Further, except when carrier tape T is rewound in the reverse direction, the original function of cover 57 can be maintained by setting cover 57 to the closed state.

### 8. Application and Modification of Embodiment

In the embodiment, fixing cover 55 can be omitted to increase the size of cover 57 that rotates and swings. Further, one or more of entry restriction section 6, opening restriction section 7, and detection section 8 may be omitted. Further, entry restriction section 6 and opening restriction section 7 do not need to be a pair of left and right sections, and either one may be omitted. Other various applications and modifications can also be made to the embodiment.

### REFERENCE SIGNS LIST

1: component mounter, 10: base, 11: table attachment section, 2: board conveyance device, 3: component supply device, 31: component supply wheeled platform, 4: component transferring device, 5: feeder table, 51: bottom plate section, 52: slot, 55: fixing cover, 57: cover, 6: entry restriction section, 61: entry restriction member, 62: cutout section, 7: opening restriction section, 71: locked member, 72: opening restriction member, 8: detection section, 81: detection bar, 82: sensor dog, 83: light blocking section, 86: photoelectric sensor, 87: light projecting section, 88: light receiving section, 8A: detection light, 9: tape feeder, 91: supply position, 92: reel holding section, 93: tape guide, 94: tape peeling section, 95: sprocket, 96: drive motor, R: reel, T: carrier tape

1. A component mounter comprising:
a base including a table attachment section;
a feeder table mounted with a tape feeder configured to feed a carrier tape that accommodates multiple components and supply the components to a predetermined supply position, the feeder table being attached to the table attachment section; and
a cover provided on the feeder table so as to be changeable between a closed state in which an upper portion of the tape feeder excluding the supply position is covered and an open state in which the upper portion is open.

2. The component mounter according to claim 1, wherein
the feeder table is detachably attached to the table attachment section, and
the component mounter further comprises an entry restriction section configured to allow the feeder table to enter the table attachment section when the cover is in the closed state and restrict the feeder table from entering the table attachment section when the cover is in the open state.

3. The component mounter according to claim 2, wherein
the entry restriction section includes
a restricted member provided on the cover, the restricted member being configured to change at least one of a position or posture thereof between the closed state and the open state of the cover, and
an entry restriction member provided on the base, the entry restriction member being configured to allow entry of the restricted member when the cover is in the closed state, the entry restriction member being configured to restrict entry of the restricted member when the cover is in the open state.

4. The component mounter according to claim 1, further comprising:
an opening restriction section configured to restrict a change of the cover from the closed state to the open state in a state in which the feeder table is attached to the table attachment section, wherein
the feeder table is detachably attached to the table attachment section.

5. The component mounter according to claim 4, wherein
the opening restriction section includes
a locked member provided on the cover, and
an opening restriction member provided on the base to lock the locked member of the cover in the closed state.

6. The component mounter according to claim 1, further comprising:
a detection section configured to detect a mounting state of the multiple tape feeders mounted on the feeder table.

7. The component mounter according to claim 6, wherein
the detection section detects that the cover is displaced in a direction from the closed state to the open state when the mounting state of one or more of the multiple tape feeders is not good.

8. The component mounter according to claim 6, further comprising:
an opening restriction section including a locked member provided on the cover and an opening restriction member provided on the base to lock the locked member of the cover in the closed state, wherein
the detection section or a member supporting the detection section also serves as the opening restriction member.

9. The component mounter according to claim 1, wherein
the cover is a safety cover configured to prevent an operator from coming into contact with the tape feeder mounted on the feeder table attached to the table attachment section.

10. The component mounter according to
claim 1, wherein
the cover is a guide cover configured to guide the tape feeder to a mounting position provided on the feeder table.
